(19) United States
(12) Patent Application Publication
(10) Pub. No.: US 2025/0036020 A1
(43) Pub. Date: Jan. 30, 2025

(54) REFLECTIVE MASK BLANK, REFLECTIVE MASK BLANK MANUFACTURING METHOD, REFLECTIVE MASK, AND REFLECTIVE MASK MANUFACTURING METHOD

(71) Applicant: AGC Inc., Tokyo (JP)

(72) Inventors: Wataru NISHIDA, Tokyo (JP); Daijiro AKAGI, Tokyo (JP); Hiroaki IWAOKA, Tokyo (JP); Hiroshi HANEKAWA, Tokyo (JP); Taiga FUDETANI, Fukushima (JP); Masaru HORI, Aichi (JP); Takayoshi TSUTSUMI, Aichi (JP)

(73) Assignee: AGC Inc., Tokyo (JP)

(21) Appl. No.: 18/911,231

(22) Filed: Oct. 9, 2024

Related U.S. Application Data
(63) Continuation of application No. PCT/JP2023/014544, filed on Apr. 10, 2023.

(30) Foreign Application Priority Data
Apr. 15, 2022 (JP) 2022-067594

(51) Int. Cl. G03F 1/24; G03F 1/48; G03F 1/52; G03F 1/54

(52) U.S. Cl. CPC G03F 1/24; G03F 1/48; G03F 1/52; G03F 1/54

(57) ABSTRACT

A reflective mask blank includes: a substrate, a multilayer reflective film including molybdenum layers and silicon layers alternately and being configured to reflect EUV light, an intermediate film, a protective film, and an absorber film, in this order, in which the intermediate film includes silicon and nitrogen, an atomic weight ratio of a content of the nitrogen to a content of the silicon is 0.22 to 0.40 or 0.15 or less, the protective film includes one or more layers selected from the group consisting of a layer including rhodium and a layer including a rhodium-containing material, and the rhodium-containing material includes rhodium and one or more elements selected from the group consisting of boron, carbon, nitrogen, oxygen, silicon, titanium, zirconium, niobium, molybdenum, ruthenium, palladium, tantalum, and iridium.

### CROSS-REFERENCE TO RELATED APPLICATIONS

This is a bypass continuation of International Patent Application No. PCT/JP2023/014544, filed on Apr. 10, 2023, which claims priority to Japanese Patent Application No. 2022-067594, filed on Apr. 15, 2022. The contents of these applications are hereby incorporated by reference in their entireties.

### TECHNICAL FIELD

The present invention relates to a reflective mask used for Extreme Ultra Violet (EUV) exposure used in an exposure process for semiconductor manufacturing, a method for manufacturing the same, a reflective mask blank which is an original plate of the reflective mask, and a method for manufacturing the same.

### BACKGROUND ART

In recent years, EUV lithography using EUV light having a center wavelength of about 13.5 nm as a light source has been studied for further miniaturization of a semiconductor device.

In the EUV exposure, a reflective optical system and a reflective mask are used according to characteristics of EUV light. In the reflective mask, a multilayer reflective film that reflects the EUV light is formed on a substrate, and an absorber film that absorbs the EUV light is patterned on the multilayer reflective film. A protective film is often provided between the multilayer reflective film and the absorber film for the purpose of protecting the multilayer reflective film at the time of patterning the absorber film.

The EUV light incident on the reflective mask due to an illumination optical system of an exposure apparatus is reflected at portions without the absorber film (openings) and absorbed at portions with the absorber film (non-openings). As a result, a mask pattern is transferred as a resist pattern onto a wafer through a reduction projection optical system of the exposure apparatus, and the subsequent processing is performed.

On the other hand, it is known that in EUV lithography, exposure contamination occurs in which a carbon film is deposited on a reflective mask by EUV light.

Here, in order to suppress exposure contamination, a method of introducing hydrogen gas into an exposure atmosphere has been studied. When hydrogen gas is introduced into the exposure atmosphere, the reflective mask comes into contact with active hydrogen, and at this time, the protective film may float and peel off at an interface with the multilayer reflective film (hereinafter, such a phenomenon of film peeling is referred to as “blisters”).

In the reflective mask blank described in Patent Literature 1, it is disclosed that occurrence of the blisters is suppressed.

### CITATION LIST

### Patent Literature

Patent Literature 1: WO2021/200325

### SUMMARY OF INVENTION

As a reflective mask blank described in Patent Literature 1, a reflective mask blank including a silicon-containing Si material layer between a protective film and a multilayer reflective film is disclosed, and a film of silicon nitride or the like is disclosed as the Si material layer. The present inventors have studied the reflective mask blank, and have found that blisters may be generated when the reflective mask blank is used as a reflective mask and that there is room for improvement.

Accordingly, an object of the present invention is to provide a reflective mask blank capable of suppressing occurrence of blisters between a multilayer reflective film and a protective film when used as a reflective mask under a hydrogen atmosphere.

In addition, another object of the present invention is to provide a method for manufacturing the reflective mask blank, a method for manufacturing a reflective mask using the reflective mask blank, and a reflective mask.

As a result of intensive studies on the above problems, the present inventors have found that the above problems can be solved when an intermediate film is provided between a multilayer reflective film and a protective film, a material constituting the intermediate film contains silicon and nitrogen, and an atomic weight ratio of a content of nitrogen to a content of silicon is within a predetermined range, thereby completing the present invention.

That is, the inventors have found that the above problems can be solved by the following configurations.

[1] A reflective mask blank including:
a substrate, a multilayer reflective film including molybdenum layers and silicon layers alternately and being configured to reflect EUV light, an intermediate film, a protective film, and an absorber film, in this order, in which
the intermediate film includes silicon and nitrogen,
an atomic weight ratio of a content of the nitrogen to a content of the silicon is 0.22 to 0.40 or 0.15 or less,
the protective film includes one or more layers selected from the group consisting of a layer including rhodium and a layer including a rhodium-containing material, and
the rhodium-containing material includes rhodium and one or more elements selected from the group consisting of boron, carbon, nitrogen, oxygen, silicon, titanium, zirconium, niobium, molybdenum, ruthenium, palladium, tantalum, and iridium.

[2] The reflective mask blank according to [1], in which the rhodium-containing material includes rhodium and one or more elements selected from the group consisting of boron, carbon, nitrogen, oxygen, silicon, titanium, zirconium, niobium, molybdenum, palladium, tantalum, and iridium.

[3] The reflective mask blank according to [1] or [2], in which the atomic weight ratio of the content of the nitrogen to the content of the silicon is 0.22 to 0.40.

[4] The reflective mask blank according to [1] or [2], in which the atomic weight ratio of the content of the nitrogen to the content of the silicon is 0.27 to 0.40.

[5] The reflective mask blank according to any of [1] to [4], in which the intermediate film further includes oxygen, and
an atomic weight ratio of a content of the oxygen to the content of the silicon is 0.29 or more.

[6] The reflective mask blank according to any one of [1] to [5], in which the intermediate film has a thickness of 0.2 nm to 5.0 nm.

[7] The reflective mask blank according to any of [1] to [6], in which the protective film includes multiple layers, and
the protective film includes a layer including a ruthenium-containing material and the layer including the rhodium-containing material in order from a side in contact with the intermediate film.

[8] The reflective mask blank according to any of [1] to [7], in which the protective film has a thickness of 1 nm to 10 nm.

[9] A method for manufacturing the reflective mask blank according to any of [1] to [8], including:
forming the multilayer reflective film on or above the substrate;
forming the intermediate film on or above the multilayer reflective film;
forming the protective film on or above the intermediate film; and
forming the absorber film on or above the protective film.

[10] The method for manufacturing the reflective mask blank according to [7], in which the multilayer reflective film is formed by sputtering,
the intermediate film is formed without exposing the formed multilayer reflective film to atmosphere, and
the protective film is formed by sputtering without exposing the formed intermediate film to atmosphere.

[11] A reflective mask having an absorber film pattern formed by patterning the absorber film of the reflective mask blank according to any of [1] to [8].

[12] A method for manufacturing a reflective mask, including:
patterning the absorber film of the reflective mask blank according to any of [1] to [8].

According to the present invention, it is possible to provide a reflective mask blank capable of suppressing occurrence of blisters between a multilayer reflective film and a protective film when used as a reflective mask under a hydrogen atmosphere. According to the present invention, it is also possible to provide a method for manufacturing the reflective mask blank, a method for manufacturing a reflective mask using the reflective mask blank, and a reflective mask.

### BRIEF DESCRIPTION OF DRAWINGS

FIG. 1 is a schematic diagram illustrating an example of an embodiment of a reflective mask blank according to the present invention.

FIG. 2 is a schematic diagram illustrating an example of the embodiment of the reflective mask blank according to the present invention.

Each of FIGS. 3A to 3D is a schematic diagram illustrating an example of a manufacturing process of a reflective mask using the reflective mask blank according to the present invention.

### DESCRIPTION OF EMBODIMENTS

Hereinafter, the present invention will be described in detail.

Constituent elements described below may be described based on representative embodiments of the present invention, but the present invention is not limited to such embodiments.

Meanings of the respective descriptions in the present description are shown.

In the present description, the symbol “-” or the word “to” that is used to express a numerical range includes the numerical values before and after the symbol or the word as the upper limit and the lower limit of the range, respectively.

In the present description, elements such as hydrogen, boron, carbon, nitrogen, oxygen, silicon, titanium, zirconium, niobium, molybdenum, ruthenium, rhodium, palladium, tantalum, and, iridium may be represented by corresponding element symbols (H, B, C, N, O, Si, Ti, Zr, Nb, Mo, Ru, Rh, Pd, Ta, and, Ir).

### <Reflective Mask Blank>

A reflective mask blank according to the present embodiment includes, in the following order on or above a substrate, a multilayer reflective film that is formed by alternately laminating Mo layers and Si layers and reflects EUV light, an intermediate film, a protective film, and an absorber film. The intermediate film contains Si and N, and an atomic weight ratio of a content of N to a content of Si is 0.22 to 0.40 or 0.15 or less, the protective film includes one or more layers selected from the group consisting of a layer including rhodium and a layer including a rhodium-containing material, and the rhodium-containing material contains Rh and one or more elements selected from the group consisting of B, C, N, O, Si, Ti, Zr, Nb, Mo, Ru, Pd, Ta, and Ir.

The reflective mask blank according to the present embodiment will be described with reference to the drawings.

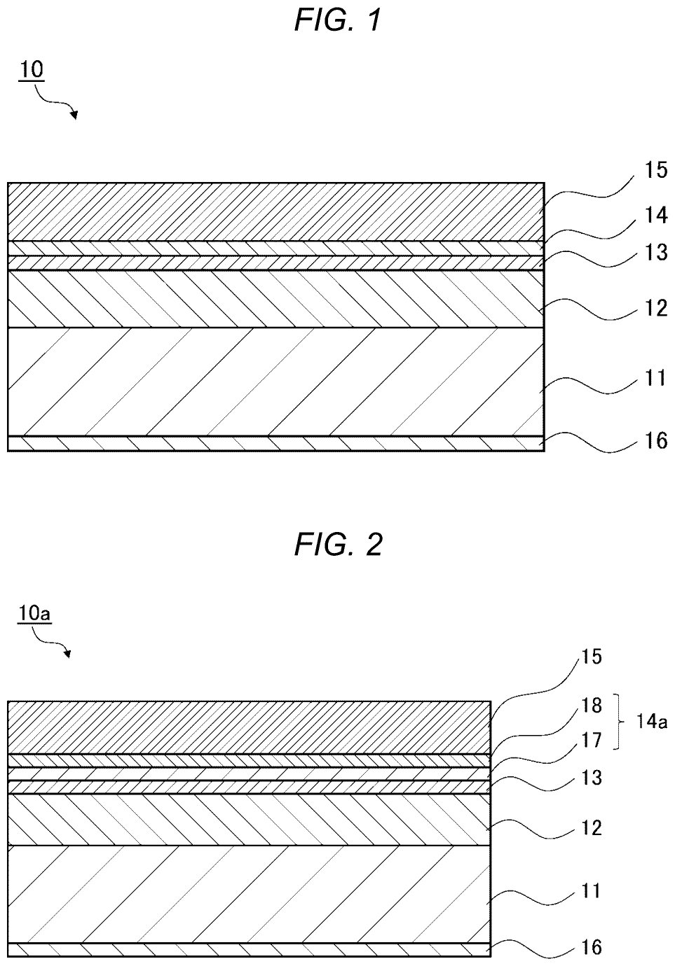

FIG. 1 is a cross-sectional view illustrating an example of an embodiment of the reflective mask blank according to the present invention. A reflective mask blank 10 illustrated in FIG. 1 includes, in the following order, a substrate 11, a multilayer reflective film 12, an intermediate film 13, a protective film 14, and an absorber film 15.

As illustrated in FIG. 1, the reflective mask blank 10 may include a back surface conductive film 16 on a surface of the substrate 11 opposite to the multilayer reflective film 12.

The multilayer reflective film 12, the intermediate film 13, and the protective film 14 satisfy requirements of the reflective mask blank according to the present embodiment.

Here, the reflective mask is prepared by patterning the absorber film 15 using the reflective mask blank 10, and can be used under a hydrogen gas atmosphere. At this time, the reflective mask is in contact with at least one of hydrogen gas in an exposure atmosphere and active hydrogen generated by EUV light. In a region where the protective film 14 of the reflective mask is exposed, the reflective mask is in direct contact with at least one of hydrogen gas and active hydrogen.

It is considered that hydrogen may enter the inside of the protective film 14 due to the small atoms thereof, in a case where there is a defect or the like in the inside of each film or at the interface of the film, the hydrogen is likely to remain in the portion, and in a case where the hydrogen exceeds a certain amount, bubbles are generated, and blisters occur.

Here, in the intermediate film 13, in a case where the atomic weight ratio of the content of N to the content of Si is 0.22 to 0.40, an interatomic distance of a material constituting the intermediate film 13 and an interatomic distance of a material constituting the protective film 14 are values close to each other, and therefore, it is considered that an interface with few defects is easily formed.

On the other hand, when the atomic weight ratio of the content of N to the content of Si is 0.15 or less, Si contained in the intermediate film 13 and Rh contained in the protective film 14 are easily mixed, and it is considered that an interface with few defects is easily formed.

In addition, Rh contained in the protective film 14 has high affinity with Si contained in the intermediate film 13, and it is considered that an interface with fewer defects is easily formed.

As a result, it is considered that the reflective mask blank according to the present embodiment can suppress occurrence of blisters between the multilayer reflective film and the protective film.

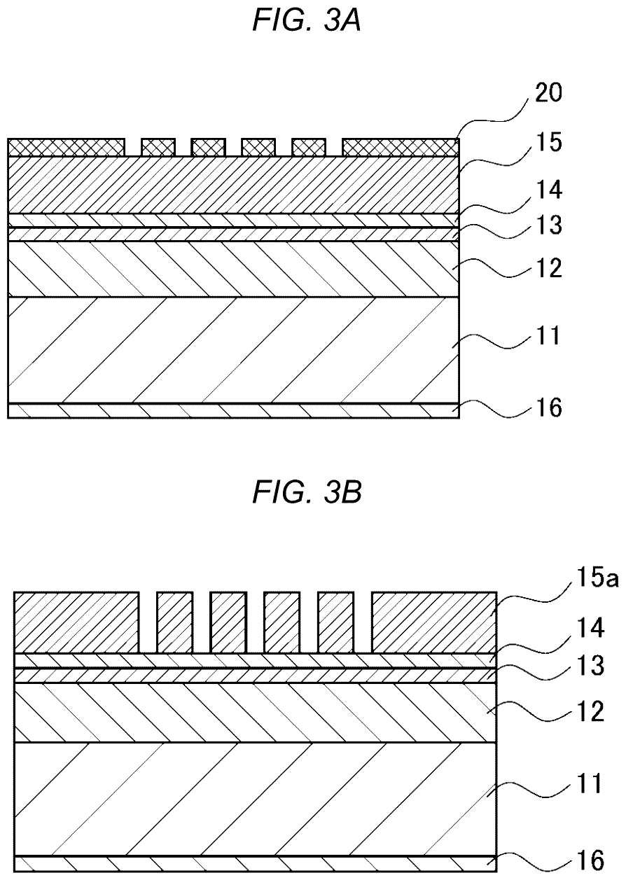

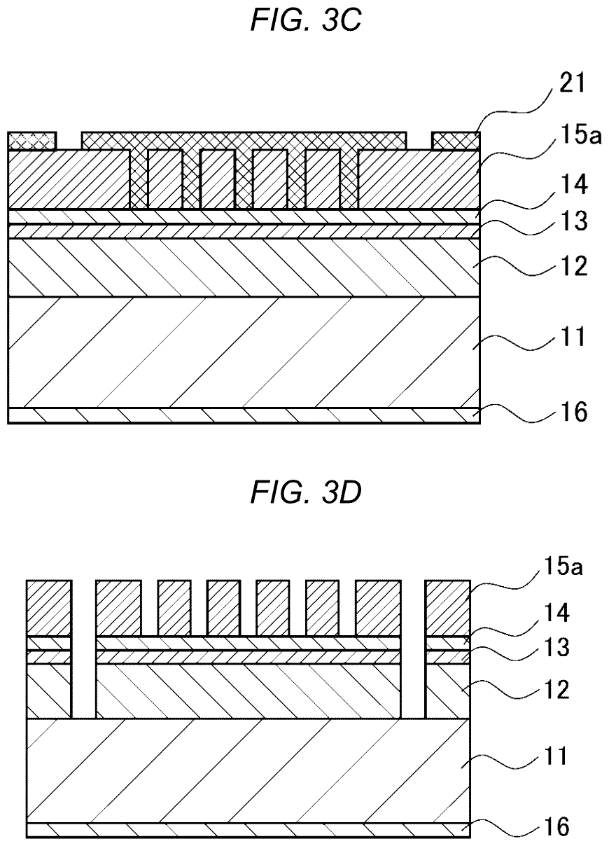

In the reflective mask blank 10 illustrated in FIG. 1, the protective film 14 is a single layer, but may be multiple layers. That is, as illustrated in FIG. 2, a reflective mask blank 10a according to the present embodiment may include, in the following order, the substrate 11, the multilayer reflective film 12, the intermediate film 13, a protective film 14a, and the absorber film 15, the back surface conductive film 16 is provided on the surface of the substrate 11 opposite to the multilayer reflective film 12, and the protective film 14a may include multiple layers of an Rh layer 18 and an Rh—Si layer 17.

It is considered that the multilayer reflective film 12, the intermediate film 13, and the protective film 14a satisfy the requirements of the reflective mask blank according to the present embodiment, and the reflective mask blank 10a illustrated in FIG. 2 can suppress the occurrence of blisters between the multilayer reflective film and the protective film for the same reason as the reflective mask blank 10 illustrated in FIG. 1.

Hereinafter, the configuration of the reflective mask blank according to the present embodiment will be described.

Hereinafter, suppression of occurrence of blisters between the multilayer reflective film and the protective film when the reflective mask formed using the reflective mask blank according to the present embodiment is used under a hydrogen atmosphere is also simply referred to as “suppression of occurrence of blisters”.

### (Substrate)

The substrate included in the reflective mask blank according to the present embodiment preferably has a small thermal expansion coefficient. When the thermal expansion coefficient of the substrate is small, it is possible to suppress occurrence of distortion in the absorber film pattern due to heat at the time of exposure with EUV light.

The thermal expansion coefficient of the substrate at 20° C. is preferably 0±1.0×10⁻⁷/° C., and more preferably 0±0.3×10⁻⁷/° C.

Examples of a material having a small thermal expansion coefficient include an SiO₂—TiO₂-based glass, but without being limited thereto, it is also possible to use a substrate of a crystallized glass in which a 3-quartz solid solution is precipitated, a quartz glass, a metallic silicon, metal or the like.

The SiO₂—TiO₂-based glass is preferably a quartz glass containing 90 mass % to 95 mass % of SiO₂ and 5 mass % to 10 mass % of TiO₂. In a case where the content of TiO₂ is 5 mass % to 10 mass %, a linear expansion coefficient around room temperature is substantially zero, and a dimensional change around room temperature hardly occurs. The SiO₂—TiO₂-based glass may contain trace components other than SiO₂ and TiO₂.

A surface of the substrate on which the multilayer reflective film is laminated (hereinafter also referred to as “first main surface”) preferably has high surface smoothness. The surface smoothness of the first main surface can be evaluated by surface roughness. The surface roughness of the first main surface is preferably 0.15 nm or less in terms of root mean square roughness Rq. The surface roughness can be measured with an atomic force microscope, and the surface roughness is described as the root mean square roughness Rq based on JIS-B 0601:2013.

The first main surface is preferably subjected to surface processing so as to have predetermined flatness from the viewpoint of enhancing pattern transfer accuracy and positional accuracy of a reflective mask obtained using the reflective mask blank. The flatness of the substrate in a predetermined region (for example, 132 mm×132 mm region) of the first main surface is preferably 100 nm or less, more preferably 50 nm or less, and further preferably 30 nm or less. The flatness can be measured by a flatness measuring instrument manufactured by Fujinon Corporation.

A size, a thickness, and the like of the substrate are appropriately determined according to design values and the like of the mask. For example, an outer shape may be 6 inches (152 mm) square, and the thickness may be 0.25 inches (6.3 mm).

Further, the substrate preferably has high rigidity from the viewpoint of preventing deformation due to film stress of films (such as multilayer reflective film and absorber film) formed on the substrate. For example, the Young's modulus of the substrate is preferably 65 GPa or more.

### (Multilayer Reflective Film)

The multilayer reflective film of the reflective mask blank according to the present embodiment is formed by alternately laminating Mo layers and Si layers. The multilayer reflective film preferably has high reflectance for EUV light, and specifically, when the EUV light is incident on a surface of the multilayer reflective film at an incident angle of 6°, the maximum value of the EUV light reflectance in the vicinity of a wavelength of 13.5 nm is preferably 60% or more, and more preferably 65% or more. Similarly, even when the protective film is laminated on the multilayer reflective film, the maximum value of the EUV light reflectance in the vicinity of the wavelength of 13.5 nm is preferably 60% or more, and more preferably 65% or more.

The Si layer may contain an element other than Si. Examples of the element other than Si include one or more elements selected from the group consisting of B, C, and O.

The Mo layer may contain an element other than Mo. Examples of the element other than Mo include one or more elements selected from the group consisting of Ru, Rh, and Pt.

In the multilayer reflective film, the Mo layer functions as a low-refractive-index layer, and the Si layer functions as a high-refractive-index layer.

The multilayer reflective film may be obtained by lamination for a plurality of cycles with, as one cycle, a laminated structure in which the Si layer and the Mo layer are laminated in this order from the substrate side, or may be obtained by lamination for a plurality of cycles with, as one cycle, a laminated structure in which the Mo layer and the Si layer are laminated in this order.

A thickness of each of the layers constituting the multilayer reflective film and the number of repeating units of the layer can be appropriately selected according to a film material to be used and the EUV light reflectance required for the reflective layer. In order to obtain a multilayer reflective film having the maximum value of the EUV light reflectance of 60% or more, an Mo layer having a thickness of 2.3±0.1 nm and an Si layer having a thickness of 4.5±0.1 nm may be laminated such that the number of repeating units is 30 to 60.

Each of the layers constituting the multilayer reflective film can be formed to have a desired thickness by using a known film forming method such as magnetron sputtering or ion beam sputtering. For example, when the multilayer reflective film is prepared using ion beam sputtering, ion particles are supplied from an ion source to a target of an Si material and a target of an Mo material. More specifically, an Si layer having a predetermined thickness is first formed on the substrate by ion beam sputtering by using, for example, an Si target. Thereafter, an Mo layer having a predetermined thickness is formed by using an Mo target. An Mo/Si multilayer reflective film is formed by lamination for 30 cycles to 60 cycles with the Si layer and the Mo layer as one cycle.

A layer of the multilayer reflective film in contact with the intermediate film is preferably a layer including a material that is hardly oxidized. The layer including a material that is hardly oxidized functions as a cap layer for the multilayer reflective film. Examples of the layer including a material that is hardly oxidized include an Si layer. When the multilayer reflective film is an Si/Mo multilayer reflective film, the layer in contact with the intermediate film functions as the cap layer in a case where the layer in contact with the intermediate film is an Si layer. In this case, a thickness of the cap layer may be 11±2 nm.

### (Intermediate Film)

The intermediate film of the reflective mask blank according to the present embodiment contains Si and N, and the atomic weight ratio of the content of N to the content of Si is 0.22 to 0.40 or 0.15 or less.

The intermediate film contains Si and N, when the atomic weight ratio of the content of N to the content of Si is 0.22 to 0.40, the silicon layer appropriately nitrided suppresses the penetration of hydrogen, and when the atomic weight ratio is 0.15 or less, a mixed layer with the protective film is formed, the interface adhesion is improved, and therefore, it is considered that the occurrence of blisters can be suppressed.

When the atomic weight ratio of the content of N to the content of Si is in a range of 0.22 to 0.40, the atomic weight ratio is preferably 0.25 to 0.40, and more preferably 0.27 to 0.40.

When the atomic weight ratio of the content of N to the content of Si is in a range of 0.15 or less, the atomic weight ratio is preferably 0.0 to 0.15, and more preferably 0.05 to 0.15. The intermediate film may further contain O because the occurrence of blisters can be suppressed. An atomic weight ratio of a content of O to the content of Si is preferably 0.29 or more, more preferably 0.30 to 1.0, further preferably 0.30 to 0.50, and particularly preferably 0.30 to 0.35. Here, the atomic weight ratio of the content of O to the content of Si is preferably 0.29 or more, more preferably 0.30 or more, and is more preferably 1.0 or less, further preferably 0.50 or less, and particularly preferably 0.35 or less.

By the intermediate film further containing O and the atomic weight ratio of the content of O to the content of Si being 0.29 or more, the intermediate film becomes dense, diffusion of hydrogen into the film is suppressed, and it is considered that occurrence of blisters can be suppressed.

A thickness of the intermediate film is preferably 0.2 nm to 5.0 nm, more preferably 0.2 nm to 4.0 nm, further preferably 0.2 nm to 3.0 nm, and particularly preferably 0.2 nm to 2.8 nm.

The thickness of the intermediate film is determined by preparing a thin section of the reflective mask blank using a focused ion beam (FIB) apparatus and analyzing the thin section by scanning transmission electron microscope-energy-dispersive X-ray spectroscopy (STEM-EDS).

The thickness of the intermediate film is a distance from an interface position between the intermediate film and the multilayer reflective film to an interface position between the intermediate film and the protective film.

The interface position between the intermediate film and the multilayer reflective film is determined as follows. A peak intensity of N is determined in a profile in a thickness direction of the reflective mask blank obtained by STEM-EDS analysis. When viewed from a multilayer reflective film side, a point where the intensity of N starts to become larger than ½ of the peak intensity of N on the profile is defined as the interface position between the intermediate film and the multilayer reflective film.

In addition, the interface position between the intermediate film and the protective film is determined as follows.

In the same manner as described above, the peak intensity of N is determined in the profile in the thickness direction of the reflective mask blank obtained by STEM-EDS analysis. When viewed from a protective film side, a point where the intensity of N starts to become larger than ½ of the peak intensity of N on the profile is defined as the interface position between the intermediate film and the protective film.

In the STEM-EDS analysis, carbon coating is performed on a surface of a sample from the top of the protective film, a thin section of the reflective mask blank is prepared using a focused ion beam (FIB) apparatus, and the STEM-EDS analysis is performed to acquire respective peak intensities for N, Si, and O.

The atomic weight ratio of the content of N to the content of Si in the intermediate film is determined from the detected intensity of each element at a position where the peak intensity of N determined by the above-described method becomes the maximum value.

The atomic weight ratio of the content of O to the content of Si is determined from a ratio of an average concentration of O to an average concentration of Si in the intermediate film. An average concentration of an element A in the intermediate film refers to a content of the element A on an atomic weight basis determined in a region of the intermediate film in the profile in the thickness direction of the reflective mask blank obtained by STEM-EDS analysis on the thin section in the same manner as described above. More specifically, profiles in the thickness direction are obtained at five portions, and an average value of average concentrations at the five portions is defined as the average concentration of the element A. The expression “determined in the region of the intermediate film” means that the content of the element A is analyzed in a range from the interface position between the intermediate film and the multilayer reflective film to the interface position between the intermediate film and the protective film. The element A here refers to O and Si.

The content of N in the intermediate film is preferably 3 atomic % to 30 atomic %, and more preferably 5 atomic % to 25 atomic % with respect to all atoms of the intermediate film. The content of N is determined from the detected intensity of each element at the position where the peak intensity of N is the maximum value in the profile obtained by the above-described method.

When the content of Si of the intermediate film is measured by a method for determining the content of N, the content of Si is preferably 10 atomic % to 95 atomic %, and more preferably 20 atomic % to 90 atomic % with respect to all atoms of the intermediate film. Here, the content of Si in the intermediate film is, with respect to all atoms in the intermediate film, preferably 10 atomic % or more, and more preferably 20 atomic % or more, and is preferably 95 atomic % or less, and more preferably 90 atomic % or less.

When the intermediate film contains O, the content of 0 in the intermediate film is preferably 5 atomic % to 30 atomic %, and more preferably 8 atomic % to 25 atomic % with respect to all atoms in the intermediate film. The content of O is an average concentration of O in the intermediate film. Here, the content of O in the intermediate film is, with respect to all atoms in the intermediate film, preferably 5 atomic % or more, and more preferably 8 atomic % or more, and is preferably 30 atomic % or less, and more preferably 25 atomic % or less.

The content of Si in the intermediate film (average concentration of Si in intermediate film) is preferably 20 atomic % to 80 atomic %, and more preferably 30 atomic % to 70 atomic % with respect to all atoms in the intermediate film. Here, the content of Si in the intermediate film is, with respect to all atoms in the intermediate film, preferably 20 atomic % or more, and more preferably 30 atomic % or more, and is preferably 80 atomic % or less, and more preferably 70 atomic % or less.

The intermediate film may contain an element other than Si, N, and O. Examples of the other elements include B, C, and elements that may be contained in the protective film to be described below.

In a case where the intermediate film contains other elements, a total content thereof is preferably more than 0 atomic % and 70 atomic % or less, and preferably more than 0 atomic % and 60 atomic % or less with respect to all atoms in the intermediate film, when measured by the method for determining the content of N described above.

It is preferable that the intermediate film do not reduce the high reflectance of the EUV light that is exhibited by the multilayer reflective film. In this respect, the intermediate film preferably has high transmittance of EUV light. In view of high transmittance of EUV light, the atomic weight ratio of the content of N to the content of Si in the intermediate film is preferably 0.22 to 0.40, and more preferably 0.27 to 0.40. Here, the atomic weight ratio of the content of N to the content of Si is preferably 0.22 or more, and more preferably 0.27 or more, and is preferably 0.40 or less, more preferably 0.35 or less, and further preferably 0.30 or less.

A crystalline state of the intermediate film may be crystalline or amorphous, and amorphous is preferable.

The intermediate film can be formed to a desired thickness by a known film forming method such as magnetron sputtering or ion beam sputtering. For example, when the intermediate film is prepared using ion beam sputtering, ion particles are supplied from an ion source to an Si target, and nitrogen gas is contained in a film forming atmosphere. In addition, in a case where an amount and a ratio of the gas contained in the film forming atmosphere is changed, the ratio of each element contained in the intermediate film can be adjusted.

In addition, as a method for forming the intermediate film, a method of forming an Si layer as the uppermost layer of the multilayer reflective film and then nitriding a surface of the Si layer to form an intermediate film may be used. Examples of the nitriding method include a method of irradiating plasma containing N (for example, high-frequency plasma). As conditions in the method of irradiating plasma containing N, for example, the following conditions are preferable.
Frequency of high-frequency plasma apparatus: 1.8 MHz
Power supplied to high-frequency plasma apparatus: 300 W to 1,000 W
Gas type of plasma irradiation atmosphere: mixed gas of Ar gas and N₂ gas (volume ratio of N₂ gas to Ar gas: 1.5 to 4.5)
Total pressure of plasma irradiation atmosphere: 8.0×10⁻³ Pa to 8.0×10⁻² Pa
Nitrogen partial pressure in plasma irradiation atmosphere: 5.2×10⁻³ Pa to 3.0×10⁻² Pa
Irradiation time: 100 seconds to 1,000 seconds (more preferably 200 seconds to 800 seconds)
Exposure amount: 5.0×10⁻¹ Pa·s to 4.8×10¹ Pa·s

In a case where the plasma irradiation conditions are changed, the ratio of each element contained in the intermediate film can be adjusted.

After the multilayer reflective film is formed, the intermediate film may be formed on the multilayer reflective film without exposing the formed multilayer reflective film to the atmosphere. As a specific procedure, for example, the formation of the multilayer reflective film and the formation of the intermediate film may be performed in the same film forming chamber. In addition, it is preferable that after the multilayer reflective film be formed, the intermediate film be formed without performing a treatment on the surface of the multilayer reflective film, such as formation of another film and surface treatment.

### (Protective Film)

The protective film included in the reflective mask blank according to the present embodiment is provided for the purpose of protecting the multilayer reflective film so that the multilayer reflective film is not damaged by an etching process (usually, dry etching process) at the time of forming a pattern on the absorber film by the etching process.

The protective film includes one or more layers selected from the group consisting of a layer including Rh and a layer including an Rh-containing material, and the Rh-containing material contains Rh and one or more elements selected from the group consisting of B, C, N, O, Si, Ti, Zr, Nb, Mo, Ru, Pd, Ta, and Ir.

In the layer including the Rh-containing material, a content of Rh in the Rh-containing material is preferably 30 atomic % or more and 100 atomic % or less, and more preferably 30 atomic % or more and less than 99 atomic %.

The Rh-containing material preferably contains Rh and one or more elements selected from the group consisting of B, C, N, O, Si, Ti, Zr, Nb, Mo, Pd, Ta, and Ir.

The layer including Rh is a layer substantially made of Rh, and substantially means that 99 atomic % or more of the layer including Rh is Rh.

When a content of Rh is within the above range, the protective film may function as an etching stopper when the absorber film is etched while sufficiently ensuring the reflectance of EUV light. Furthermore, cleaning resistance can be imparted to the reflective mask, and deterioration over time of the multilayer reflective film can be prevented.

A thickness of the protective film is not particularly limited as long as it can function as the protective film. From the viewpoint of maintaining the reflectance of EUV light reflected by the multilayer reflective film, the thickness of the protective film is preferably 1 nm to 10 nm, more preferably 1.5 nm to 6 nm, and further preferably 2 nm to 5 nm. Here, the thickness of the protective film is preferably 1 nm or more, more preferably 1.5 nm or more, and further preferably 2 nm or more, and is preferably 10 nm or less, more preferably 6 nm or less, and further preferably 5 nm or less.

The protective film can be formed by a known film forming method such as magnetron sputtering and ion beam sputtering.

Conditions for forming the layer including Rh are preferably, for example, the following conditions.
Film forming method: DC sputtering
Target: Rh target
Sputtering gas: Ar (gas partial pressure: 1.0×10⁻² Pa to 1.0×10⁰ Pa)
Supplied power density per target area: 1.0 W/cm² to 8.5 W/cm²
Film formation rate: 0.020 nm/sec to 1.000 nm/sec

After the intermediate film is formed, the protective film may be formed on the intermediate film without exposing the formed intermediate film to the atmosphere. As a specific procedure, for example, the formation of the intermediate film and the formation of the protective film may be performed in the same film forming chamber. It is preferable that after the intermediate film be formed, the protective film be formed without performing a treatment on the surface of the multilayer reflective film, such as formation of another film and surface treatment.

Among them, it is preferable that the multilayer reflective film be formed by sputtering, the intermediate film be formed without exposing the formed multilayer reflective film to the atmosphere, and the protective film be formed by sputtering without exposing the formed intermediate film to the atmosphere. By continuously forming the films without being exposed to the atmosphere, it is possible to suppress formation of an oxide which may cause a decrease in reflectance. In addition, it is more preferable that after the multilayer reflective film be formed, the formation of the intermediate film be completed, the formation of the protective film be completed, and then the formation of the films be continuously performed without being exposed to the atmosphere until the absorber film be formed.

As described above, the protective film may include multiple layers.

When the protective film include multiple layers, the protective film preferably includes a layer including an Rh-containing material and a layer including Rh from a side in contact with the intermediate film, and more preferably includes an Rh—Si-containing layer and a layer including Rh.

The Rh—Si-containing layer is a layer including an Rh-containing material containing Rh and Si. The Rh—Si-containing layer may contain elements other than Rh and Si, and may contain elements that may be contained in the Rh-containing material.

In the Rh—Si-containing layer, an atomic weight ratio of a content of Rh to a content of Si is preferably 1.0 to 15.0, more preferably 5.0 to 15.0, further preferably 10.0 to 15.0, and particularly preferably 12.5 to 15.0. Here, the atomic weight ratio of the content of Rh to the content of Si is preferably 1.0 or more, more preferably 5.0 or more, further preferably 10.0 or more, and particularly preferably 12.5 or more, and preferably 15.0 or less.

A thickness of the Rh—Si-containing layer is preferably 0.5 nm or more and less than 2.5 nm, more preferably 1.0 nm or more and less than 2.5 nm, and further preferably 1.0 nm to 2.3 nm. In a case where the thickness of the Rh—Si-containing layer is in a further preferable range, a decrease in the reflectance of the EUV light of the reflective mask blank can be suppressed. Here, the thickness of the Rh—Si-containing layer is preferably 0.5 nm or more, and more preferably 1.0 nm or more, and is preferably less than 2.5 nm, and further preferably 1.0 nm to 2.3 nm.

When the protective film includes the Rh—Si-containing layer and the layer including Rh from the side in contact with the intermediate film and the two layers are adjacent to each other, the thickness of the Rh—Si-containing layer is a distance from an interface position between the layer including Rh and the Rh—Si-containing layer to an interface position between the Rh—Si-containing layer and the intermediate film.

The interface position between the layer including Rh and the Rh—Si-containing layer is determined as follows. A profile in the thickness direction of the reflective mask blank obtained by STEM-EDS is obtained in the same manner as in the method of measuring the thickness of the intermediate film. When viewed from a side of the layer including Rh, a point where the atomic weight ratio of the content of Si to the content of Rh is 0.07 or more on the profile is defined as the interface position between the layer including Rh and the Rh—Si-containing layer.

The interface position between the Rh—Si-containing layer and the intermediate film is determined as follows. The peak intensity of N is determined in the profile in the thickness direction of the reflective mask blank obtained by STEM-EDS analysis in the same manner as in the method of measuring the thickness of the intermediate film. When viewed from the protective film side, a point where the intensity of N starts to become smaller than ½ of the peak intensity of N on the profile is defined as the interface position between the Rh—Si containing layer and the intermediate film.

The atomic weight ratio of the content of Rh to the content of Si in the Rh—Si-containing layer is determined from a ratio of an average concentration of Rh to an average concentration of Si in the Rh—Si-containing layer. Definition of the average concentration is as described above, and the average concentration is determined by performing analysis in a region of the Rh—Si-containing layer.

In addition, the protective film may include a single layer, or may include multiple layers described below.

When the protective film includes multiple layers, it is more preferable that the protective film include a layer including an Ru-containing material and a layer including an Rh-containing material in order from the side in contact with the intermediate film.

The layer including the Rh-containing material may contain only Rh or may contain Rh and an element other than Rh. Among the materials contained in the layer including the Rh-containing material, Rh is preferably contained in the largest amount on an at % basis (atomic % basis), and the content of Rh in the Rh-containing material is preferably 30 atomic % or more and 100 atomic % or less. It is more preferable that the layer including the Rh-containing material contain Rh as a main component, that is, the content of Rh be 50 at % or more. The content of Rh in the layer including the Rh-containing material is more preferably 50 at % to 100 at %, and further preferably more than 50 at % to 100 at %. Due to the layer including the Rh-containing material, the protective film has high etching resistance against the etching gas in the etching step of the absorber film at the time of manufacturing the reflective mask.

When the layer including the Rh-containing material contains an element other than Rh, at least one element selected from the group consisting of N, O, C, B, Ru, Nb, Mo, Ta, Ir, Pd, Zr, and Ti is preferably contained as the element other than Rh.

The layer including the Rh-containing material may contain at least one element Z2 selected from the group consisting of N, O, C, and B in addition to Rh. The element Z2 reduces the durability of the protective film against the etching gas, but improves the smoothness of the protective film by reducing the crystallinity of the protective film. The layer including the Rh-containing material containing the element Z2 has an amorphous structure or a microcrystalline structure. When the layer including the Rh-containing material has an amorphous structure or a microcrystalline structure, an X-ray diffraction profile of the layer including the Rh-containing material does not have a clear peak.

When the layer including the Rh-containing material contains Z2 in addition to Rh, the content of Rh or a total content of Rh and Z1 is preferably 40 at % to 99 at %, and a total content of Z2 is preferably 1 at % to 60 at %. When an Rh compound contains Z2 in addition to Rh, the content of Rh or the total content of Rh and Z1 is more preferably 80 at % to 99 at %, and the total content of Z2 is more preferably 1 at % to 20 at %.

The layer including the Ru-containing material may contain only Ru or may include Ru and an element other than Ru. A content of Ru in the layer including the Ru-containing material is preferably 50 at % to 100 at %.

When the layer including the Ru-containing material contains an element other than Ru, at least one element selected from the group consisting of N, O, C, B, Nb, Mo, Ta, Ir, Pd, Rh, Zr, and Ti is preferably contained as the element other than Ru. When the layer including the Ru-containing material contains the above element, suppression of mixing with the intermediate film and suppression of a decrease in reflectance can be further promoted.

### (Absorber Film)

The absorber film of the reflective mask blank according to the present embodiment is required to have high contrast between the EUV light reflected by the multilayer reflective film and the EUV light in the absorber film at the time of patterning the absorber film.

The patterned absorber film (absorber film pattern) may function as a binary mask by absorbing EUV light, or may function as a phase shift mask that generates contrast by interfering with EUV light from the multilayer reflective film while reflecting EUV light.

When the absorber film pattern is used as a binary mask, the absorber film absorbs EUV light, and low EUV light reflectance is required. Specifically, it is desirable that the maximum value of the reflectance of EUV light having a wavelength in the vicinity of 13.5 nm when the surface of the absorber film is irradiated with EUV light is 2% or less.

The absorber film may contain one or more components selected from the group consisting of O, N, B, Hf, and H in addition to one or more metals selected from the group consisting of Ta, Ti, Sn, and Cr. Among them, N or B is preferably contained. By containing N or B, a crystalline state of the absorber film can be an amorphous or microcrystalline structure.

The crystalline state of the absorber film is preferably amorphous. Accordingly, the smoothness and the flatness of the absorber film are increased. In a case where the smoothness and the flatness of the absorber film are increased, the edge roughness of the absorber film pattern is reduced, and the dimensional accuracy of the absorber film pattern can be increased.

When the absorber film pattern is used as a phase shift mask, the reflectance of EUV light of the absorber film is preferably 2% or more. In order to sufficiently obtain a phase shift effect, the reflectance of the absorber film is preferably 9% to 15%. In a case where the absorber film is used as the phase shift mask, the contrast of the optical image on the wafer is improved and the exposure margin is increased.

Examples of a material for forming the phase shift mask include Ru metal simple substances, Ru alloys containing Ru and one or more metals selected from the group consisting of Cr, Au, Pt, Re, Hf, Ti, and Si, alloys of Ta and Nb, oxides containing Ru alloy or TaNb alloy and oxygen, nitrides containing Ru alloy or TaNb alloy and nitrogen, and oxynitrides containing Ru alloy or TaNb alloy, oxygen, and nitrogen.

The absorber film may be a single-layer film or a multilayer film including a plurality of films. When the absorber film is a single-layer film, the number of steps at the time of manufacturing a mask blank can be reduced, and the production efficiency can be improved. When the absorber film is a multilayer film, a layer disposed on a side of the absorber film opposite to the protective film may be an antireflection film at the time of inspecting the absorber film pattern using inspection light (for example, wavelength of 193 nm to 248 nm).

The absorber film can be formed by using a known film forming method such as magnetron sputtering and ion beam sputtering. For example, when an Ru oxide film is formed as the absorber film by using magnetron sputtering, sputtering can be performed by using an Ru target and supplying a gas containing Ar gas and oxygen gas to form the absorber film.

### (Back Surface Conductive Film)

In the reflective mask blank according to the present embodiment, a back surface conductive film may be provided on a surface (second main surface) of the substrate opposite to the first main surface. By providing the back surface conductive film, the reflective mask blank may be handled by an electrostatic chuck.

The back surface conductive film preferably has a low sheet resistance value. The sheet resistance value of the back surface conductive film is, for example, preferably 200Ω/□ or less, and more preferably 100Ω/□ or less.

A constituent material of the back surface conductive film can be widely selected from those described in known literatures. For example, coating having a high dielectric constant, specifically, coating made of Si, Mo, Cr, CrON, or TaSi, as described in JP2003-501823A, can be applied. In addition, the constituent material of the back surface conductive film may be a Cr compound containing Cr and one or more selected from the group consisting of B, N, O, and C, or a Ta compound containing Ta and one or more selected from the group consisting of B, N, O, and C.

A thickness of the back surface conductive film is preferably 10 nm to 1,000 nm, and more preferably 10 nm to 400 nm.

In addition, the back surface conductive film may provide a function of stress adjustment on a second main surface side of the reflective mask blank. That is, the back surface conductive film can perform adjustment to flatten the reflective mask blank by balancing stresses from various films formed on the first main surface side.

The back surface conductive film can be formed by a known film forming method, for example, sputtering such as magnetron sputtering or ion beam sputtering, CVD, vacuum deposition, or an electrolytic plating.

### (Other Films)

The reflective mask blank according to the present invention may include other films. Examples of the other films include a hard mask film. The hard mask film is preferably disposed on a side of the absorber film opposite to the protective film.

As the hard mask film, a material having high resistance to dry etching, such as a Cr-based film and an Si-based film, is preferably used. Examples of the Cr-based film include Cr and a material containing Cr and one or more elements selected from the group consisting of O, N, C, and H. Specific examples thereof include CrO and CrN. Examples of the Si-based film include Si and a material containing Si and one or more selected from the group consisting of O, N, C, and H. Specific examples thereof include SiO₂, SiON, SiN, SiO, Si, SiC, SiCO, SiCN, and SiCON. In a case where the hard mask film is formed on the absorber film, dry etching can be performed even when the minimum line width of the absorber film pattern becomes small. Therefore, it is effective for miniaturization of the absorber film pattern.

### <Method for Manufacturing Reflective Mask Blank>

The reflective mask blank according to the present embodiment is obtained by forming a multilayer reflective film on or above a substrate, forming an intermediate film on or above the multilayer reflective film, forming a protective film on or above the intermediate film, and forming an absorber film on or above the protective film.

Preferred configurations, formation conditions, and the like of the substrate, the multilayer reflective film, the intermediate film, the protective film, the absorber film, and any other layers are as described above.

### <Method for Manufacturing Reflective Mask and Reflective Mask>

A reflective mask is obtained by patterning an absorber film of a reflective mask blank. An example of a method for manufacturing the reflective mask will be described with reference to FIG. 3.

FIG. 3A illustrates a state where a resist pattern 20 is formed on the reflective mask blank including, in the following order, the back surface conductive film 16, the substrate 11, the multilayer reflective film 12, the intermediate film 13, the protective film 14, and the absorber film 15. A method for forming the resist pattern 20 may be a known method, and for example, a resist is applied onto the absorber film 15 of the reflective mask blank, and the resist pattern 20 is formed by performing exposure and development. The resist pattern 20 corresponds to a pattern formed on a wafer using a reflective mask.

Thereafter, the absorber film 15 is etched and patterned using the resist pattern 20 in FIG. 3A as a mask, and the resist pattern 20 is removed to obtain a laminate including an absorber film pattern 15a illustrated in FIG. 3B.

Next, as illustrated in FIG. 3C, a resist pattern 21 corresponding to a frame of an exposure region is formed on the laminate in FIG. 3B, and dry etching is performed using the resist pattern 21 in FIG. 3C as a mask. The dry etching is performed until the substrate 11 is reached. After the dry etching, the resist pattern 21 is removed to obtain a reflective mask illustrated in FIG. 3D.

Examples of the dry etching for forming the absorber film pattern 15a include dry etching using a Cl gas and dry etching using an F gas.

The resist pattern 20 or 21 may be removed by a known method, and may be removed by a cleaning solution. Examples of the cleaning solution include sulfuric peroxide mixture (SPM), sulfuric acid, ammonia water, ammonia peroxide mixture (APM), OH radical cleaning water, and ozone water.

The reflective mask formed by patterning the absorber film of the reflective mask blank according to the present embodiment can be suitably applied as a reflective mask used for exposure with EUV light. The reflective mask according to the present embodiment can suppress occurrence of blisters between the multilayer reflective film and the protective film, and can suppress a decrease in the reflectance of EUV light due to the blisters.

### EXAMPLES

Hereinafter, the present invention will be described in more detail based on the examples.

Materials, amounts used, proportions, and the like described in the following examples can be appropriately changed without departing from the gist of the present invention. Therefore, the scope of the present invention should not be construed as being limited to the following examples.

Examples 1 and 3 to 5 to be described later are inventive examples, and Examples 2 and 6 are comparative examples.

### <Preparation of Sample>

Samples for a blister occurrence test were prepared by the following procedure.

First, a silicon wafer (outer diameter: 4 inches, thickness: 0.5 mm, resistance value: 1Ω to 100Ω, orientation plane: (100)) was prepared as a substrate for film formation. Mo layers (2.3 nm) and Si layers (4.5 nm) were alternately formed on the silicon wafer by ion beam sputtering to form a multilayer reflective film (272 nm). The number of Mo layers and the number of Si layers were each 40, and film formation was performed so that the Si layer became the outermost surface. Film formation conditions for the Mo layers and the Si layers were as follows. The thickness of each layer was determined by fitting using the material and the thickness of the film as parameters by X-ray reflectance (XRR).

### (Film Formation Conditions of Mo)

Target: Mo target
Sputtering gas: Ar gas (gas partial pressure: 2×10⁻² Pa)
Acceleration voltage: 700 V
Film formation rate: 0.064 nm/sec

### (Film Formation Conditions of Si Layer)

Target: Si target (B doped)
Sputtering gas: Ar gas (gas partial pressure: 2×10⁻² Pa)
Acceleration voltage: 700 V
Film formation rate: 0.077 nm/sec

After forming the Si layer on the outermost surface of the multilayer reflective film, the Si layer on the outermost surface was irradiated with plasma generated in an atmosphere containing N₂ gas to form an intermediate film. The intermediate film was continuously formed in the same film forming chamber after the multilayer reflective film was formed. That is, the intermediate film was formed on the multilayer reflective film without exposing the multilayer reflective film to the atmosphere. Formation conditions of the intermediate film were as follows. The plasma irradiation time was changed for each sample as described later.

### (Intermediate Film Formation Conditions)

Frequency of high-frequency plasma apparatus: 1.8 MHz
Power supplied to high-frequency plasma apparatus: 500 W
Gas type of plasma irradiation atmosphere: mixed gas of Ar gas and N₂ gas (flow rate of Ar gas: 17 sccm, flow rate of nitrogen gas: 50 sccm)
Total pressure of plasma irradiation atmosphere: 3.5×10⁻² Pa
Nitrogen partial pressure in plasma irradiation atmosphere: 2.6×10⁻² Pa
Ar partial pressure in plasma irradiation atmosphere: 0.9×10⁻² Pa
Plasma irradiation time: 200 seconds, 400 seconds, 600 seconds, or 800 seconds

The expression of “sccm” represents a flow rate in a standard state, and is mL/min at 0° C. and atmospheric pressure.

The substrate on which the intermediate film was formed was exposed to the atmosphere and transferred to another chamber, and a protective film (thickness: 2.5 nm) made of Rh was formed on the intermediate film using DC sputtering. An oxygen ratio in the intermediate film was determined by the standby exposure time. Film formation conditions of the protective film were as follows. A sputtering gas partial pressure was changed for each sample as described later.
Target: Rh target
Sputtering gas: Ar gas (flow rate: 10 sccm to 50 sccm)
Sputtering gas partial pressure: 1.0×10⁻² Pa to 1.0×10⁻⁰ Pa

A protective film made of Ru which was prepared in Example 6 described later was formed by ion beam sputtering in an apparatus in which an intermediate film was formed without exposing the substrate on which the intermediate film was formed to the atmosphere. A thickness of the Ru protective film was 2.5 nm. The film formation conditions were as follows.
Target: Ru target
Sputtering gas: Ar gas (gas partial pressure: 2×10⁻² Pa)
Acceleration voltage: 700 V
Film formation rate: 0.052 nm/sec

The intermediate film and the protective film of each sample were prepared under the following conditions.

### Example 1

### <Intermediate Film Formation Conditions>

Total pressure of plasma irradiation atmosphere: 3.5×10⁻² Pa
Plasma irradiation atmosphere gas: flow rate of Ar gas: 17 sccm and flow rate of nitrogen gas: 50 sccm
Plasma irradiation time: 800 seconds

### <Protective Film Formation Conditions>

Protective film target: Rh target
Flow rate of sputtering Ar gas for protective film: 10 sccm

### Example 2

### <Intermediate Film Formation Conditions>

Total pressure of plasma irradiation atmosphere: 3.5×10⁻² Pa
Plasma irradiation atmosphere gas: flow rate of Ar gas: 17 sccm and flow rate of nitrogen gas: 50 sccm
Plasma irradiation time: 600 seconds

### <Protective Film Formation Conditions>

Protective film target: Rh target
Flow rate of sputtering gas for protective film: 50 sccm

### Example 3

### <Intermediate Film Formation Conditions>

Total pressure of plasma irradiation atmosphere: 3.5×10⁻² Pa
Plasma irradiation atmosphere gas: flow rate of Ar gas: 17 sccm and flow rate of nitrogen gas: 50 sccm
Plasma irradiation time: 600 seconds

### <Protective Film Formation Conditions>

Protective film target: Rh target
Flow rate of sputtering gas for protective film: 10 sccm

### Example 4

### <Intermediate Film Formation Conditions>

Total pressure of plasma irradiation atmosphere: 3.5×10⁻² Pa
Plasma irradiation atmosphere gas: flow rate of Ar gas: 17 sccm and flow rate of nitrogen gas: 50 sccm
Plasma irradiation time: 400 seconds

### <Protective Film Formation Conditions>

Protective film target: Rh target
Flow rate of sputtering gas for protective film: 10 sccm

### Example 5

### <Intermediate Film Formation Conditions>

Total pressure of plasma irradiation atmosphere: 3.5×10⁻² Pa
Plasma irradiation atmosphere gas: flow rate of Ar gas: 17 sccm and flow rate of nitrogen gas: 50 sccm
Plasma irradiation time: 200 seconds

### <Protective Film Formation Conditions>

Protective film target: Rh target
Flow rate of sputtering gas for protective film: 10 sccm

### Example 6

### <Intermediate Film Formation Conditions>

Total pressure of plasma irradiation atmosphere: 3.5×10⁻² Pa
Plasma irradiation atmosphere gas: flow rate of Ar gas: 17 sccm and flow rate of nitrogen gas: 50 sccm
Plasma irradiation time: 200 seconds

### <Protective Film Formation Conditions>

Target for protective film: Ru target
Flow rate of sputtering gas for protective film: 50 sccm

The thicknesses of the intermediate film and the protective film in each prepared sample were determined by the methods described in the method for measuring the thickness of the intermediate film and the method for measuring the thickness of the protective film. More specifically, a thin section of each sample was prepared using an FIB apparatus, and was observed and analyzed using STEM-EDS (ARM200F manufactured by JEOL Ltd., and EDS analyzer: JED-2300T manufactured by JEOL Ltd.). An acceleration voltage of an electron beam at the time of EDS analysis was 200 kV, and the content of each element was calculated from L line for Rh, K line for Si, K line for N, and K line for O. As analysis software, NSS manufactured by Thermo Fisher Scientific was used, and net count data was used to perform analysis by an atomic percent method.

In addition, as described above, an element ratio of the intermediate film was calculated from the content of each element at a position corresponding to a half of the thickness of the intermediate film.

The configuration of each sample is shown in the following table.

### <Evaluation on Blister Occurrence Suppression>

Each sample prepared by the above procedure was cut into a 2.5 cm square to obtain a test piece. The test piece was set on a sample stage disposed in a hydrogen irradiation test apparatus simulating an EUV exposure apparatus, and was irradiated with hydrogen (including hydrogen ions).

A surface, on the protective film side, of the test piece after the hydrogen irradiation was observed with a scanning electron microscope (SU-70 manufactured by Hitachi High-Technologies Corporation) to confirm whether blister occurred. Evaluation results are shown in the following table.

The evaluation on blister occurrence suppression was performed according to the following criteria.
A: ratio of area of blister to observation field area of SEM observation image (observation magnification of 100,000 times) after predetermined irradiation time of less than 1%.
B: ratio of area of blister to observation field area of SEM observation image (observation magnification of 100,000 times) after predetermined irradiation time of 1% or more and less than 20%
C: ratio of area of blister to observation field area of SEM observation image (observation magnification of 100,000 times) after predetermined irradiation time of 20% or more

### <Reflectance Simulation>

The reflectance of each sample was simulated to determine the reflectance of EUV light.

Optical constants of each layer in an EUV wavelength region were cited from a database provided by The Center for X-Ray Optics (CXRO). As the thickness of each film, the thickness obtained by XRR analysis was used for the multilayer reflective film, and the thickness obtained by STEM-EDS analysis was used for the other films. Simulation results are shown in the following table.

### Results

The configuration and evaluation results of each sample are shown in Table 1.

In Table 1, notations such as “Rh—Si” and “Si—O—N” in a material column represent a material containing Rh and Si and a material containing Si, O, and N, respectively.

In Table 1, the “measurement method 1” represents that the content of each element was determined by the method of determining the content of N in the intermediate film.

In Table 1, the “measurement method 2” represents that the content of each element was determined by the method of determining the content of O in the intermediate film.

In the “measurement method 2”, when the content of O and the content of Si are calculated, the measurement accuracy is higher than that in the “measurement method 1”.

In Table 1, “at %” represents atomic %.

In Table 1, in the “measurement method 3”, carbon coating is performed on the surface of the sample from the top of the protective film, a thin section of a reflective mask blank is prepared using a focused ion beam (FIB) apparatus, STEM-EDS analysis is performed to determine the contents of N and Si by the measurement method 1, and the content of O refers to a value calculated using a peak attributed to N.

TABLE 1

| | | | Example | Example | Example | Example | Example | Example |
|---|---|---|---|---|---|---|---|---|
| | | | 1 | 2 | 3 | 4 | 5 | 6 |
| Protective film | Rh layer or | Material | Rh | Rh | Rh | Rh | Rh | Ru |
| | Ru layer | Thickness | 1.2 | 0.4 | 0.8 | 0.7 | 0.4 | 0.7 |
| | | (nm) | | | | | | |
| | Rh—Si layer or | Material | Rh—Si | Rh—Si | Rh—Si | Rh—Si | Rh—Si | Ru—Si |
| | Ru—Si layer | Thickness | 1.3 | 2.1 | 1.7 | 1.8 | 2.1 | 1.8 |
| | | (nm) | | | | | | |
| Intermediate film | | Material | Si—O—N | Si—O—N | Si—O—N | Si—O—N | Si—O—N | Si—N |
| | | Thickness | 1.7 | 2.0 | 1.7 | 1.7 | 2.6 | 2.0 |
| | | (nm) | | | | | | |
| Composition of | Measurement | N (at %) | 9.8 | 8.2 | 8.5 | 9.8 | 6.3 | 9.8 |
| intermediate | method 1 | Si (at %) | 36.4 | 46.9 | 38.0 | 39.1 | 40.9 | 40.5 |
| film | | N/Si | 0.27 | 0.17 | 0.22 | 0.25 | 0.15 | 0.24 |
| | Measurement | O (at %) | 9.8 | 9.8 | 9.6 | 10.4 | 12.0 | 4.8 |
| | method 2 | Si (at %) | 32.3 | 44.3 | 36.5 | 35.3 | 36.3 | 65.1 |
| | | O/Si | 0.30 | 0.22 | 0.26 | 0.29 | 0.33 | 0.07 |
| | Measurement | N (at %) | 17.1 | 12.3 | 14.8 | 15.7 | 10.4 | 18.7 |
| | method 3 | Si (at %) | 63.4 | 70.5 | 66.0 | 62.6 | 67.4 | 77.3 |
| | | O (at %) | 11.2 | 11.4 | 11.1 | 13.6 | 13.5 | 2.1 |
| Evaluation | Blister | Evaluation | A | C | B | B | A | C |
| | occurrence | | | | | | | |
| | suppression | | | | | | | |
| | EUV light | % | 62.8 | 62.1 | 62.7 | 62.6 | 61.2 | 63.9 |
| | reflectance | | | | | | | |

Although a silicon wafer is used as the substrate in the above procedure, an SiO₂—TiO₂-based glass or the like may be used as the substrate.

When the occurrence of blisters is suppressed in the sample prepared by the above procedure, a reflective mask blank obtained by forming the absorber film on the protective film of the sample is a reflective mask obtained by patterning the absorber film, and the occurrence of blisters between the multilayer reflective film and the protective film can be suppressed when the reflective mask blank is used in a hydrogen atmosphere.

According to the results of Table 1, the occurrence of blisters cannot be suppressed in the sample of Example 2 in which the atomic weight ratio of the content of N to the content of Si is not 0.22 to 0.40 or 0.15 or less. In addition, the occurrence of blisters cannot be suppressed even in the sample of Example 6 in which Rh is not contained in the protective film.

On the other hand, it is confirmed that the occurrence of blisters is suppressed in the samples of Example 1 and Example 3 to 5 in which the atomic weight ratio is 0.22 to 0.40 or 0.15 or less.

It is confirmed from comparison between the samples of Examples 3 and 4 and the samples of Examples 1 and 5 that the occurrence of blisters can be further suppressed when the atomic weight ratio of the content of N to the content of Si in the intermediate film is 0.27 to 0.40 or 0.15 or less.

According to comparison between the sample of Example 5 and the sample of Example 1, it can be said that the sample of Example 1 in which the thickness of the Rh—Si-containing layer is 2.0 nm or less has more excellent EUV light reflectance.

Although the present invention has been described in detail with reference to specific embodiments, it is apparent to those skilled in the art that various changes and modifications can be made without departing from the spirit and scope of the present invention. The present application is based on a Japanese Patent Application (Japanese Patent Application No. 2022-067594) filed on Apr. 15, 2022, the content of which is incorporated herein by reference.

### REFERENCE SIGNS LIST

10, 10a: reflective mask blank
11: substrate
12: multilayer reflective film
13: intermediate film
14: protective film
15: absorber film
15a: absorber film pattern
16: back surface conductive film
17: Rh—Si layer
18: Rh layer
20, 21: resist pattern

What is claimed is:

1. A reflective mask blank comprising:
a substrate, a multilayer reflective film comprising molybdenum layers and silicon layers alternately and being configured to reflect EUV light, an intermediate film, a protective film, and an absorber film, in this order, wherein
the intermediate film comprises silicon and nitrogen,
an atomic weight ratio of a content of the nitrogen to a content of the silicon is 0.22 to 0.40 or 0.15 or less,
the protective film comprises one or more layers selected from the group consisting of a layer comprising rhodium and a layer comprising a rhodium-containing material, and
the rhodium-containing material comprises rhodium and one or more elements selected from the group consisting of boron, carbon, nitrogen, oxygen, silicon, titanium, zirconium, niobium, molybdenum, ruthenium, palladium, tantalum, and iridium.

2. The reflective mask blank according to claim 1, wherein the rhodium-containing material comprises rhodium and one or more elements selected from the group consisting of boron, carbon, nitrogen, oxygen, silicon, titanium, zirconium, niobium, molybdenum, palladium, tantalum, and iridium.

3. The reflective mask blank according to claim 1, wherein the atomic weight ratio of the content of the nitrogen to the content of the silicon is 0.22 to 0.40.

4. The reflective mask blank according to claim 1, wherein the atomic weight ratio of the content of the nitrogen to the content of the silicon is 0.27 to 0.40.

5. The reflective mask blank according to claim 1, wherein the intermediate film further comprises oxygen, and
an atomic weight ratio of a content of the oxygen to the content of the silicon is 0.29 or more.

6. The reflective mask blank according to claim 1, wherein the intermediate film has a thickness of 0.2 nm to 5.0 nm.

7. The reflective mask blank according to claim 1, wherein the protective film comprises multiple layers, and
the protective film comprises a layer comprising a ruthenium-containing material and the layer comprising the rhodium-containing material in order from a side in contact with the intermediate film.

8. The reflective mask blank according to claim 1, wherein the protective film has a thickness of 1 nm to 10 nm.

9. A method for manufacturing the reflective mask blank according to claim 1, comprising:
forming the multilayer reflective film on or above the substrate;
forming the intermediate film on or above the multilayer reflective film;
forming the protective film on or above the intermediate film; and
forming the absorber film on or above the protective film.

10. The method for manufacturing the reflective mask blank according to claim 9, wherein the multilayer reflective film is formed by sputtering,
the intermediate film is formed without exposing the formed multilayer reflective film to atmosphere, and
the protective film is formed by sputtering without exposing the formed intermediate film to atmosphere.

11. A reflective mask having an absorber film pattern formed by patterning the absorber film of the reflective mask blank according to claim 1.

12. A method for manufacturing a reflective mask, comprising:
patterning the absorber film of the reflective mask blank according to claim 1.
